(19) United States
(12) Patent Application Publication
(10) Pub. No.: US 2003/0049928 A1
(43) Pub. Date: Mar. 13, 2003

(54) Method of manufacturing heat dissipation device

(76) Inventor: Bo Young Lin, Taipei (TW)

Correspondence Address: Bo Young LIN, PO Box 82-144, TAIPEI, TW

(21) Appl. No.: 10/133,489

(22) Filed: Apr. 29, 2002

(30) Foreign Application Priority Data
Sep. 12, 2001 (TW) 090122688

(51) Int. Cl. H01L 21/4763

(52) U.S. Cl. 438/625

(57) ABSTRACT

A method of manufacturing heat dissipation device is disclosed. The method comprises stamping copper plates or boards of appropriate thickness to form heat dissipation seat and heat dissipation fins of appropriate shape; surface-furnishing of heat dissipation seat; surface oil-contaminant cleaning and treatment of the heat dissipation seat and heat dissipation fins under a protective gas; soldering with silver in an oven by coating the region between the heat dissipation seat and heat dissipation fins with a silver solder; performing an anti-oxidant process for copper on the heat dissipation seat and heat dissipation fins from the oven; and riveting or mounting a top cover for fixing a fan onto the heat dissipation seat.

### BACKGROUND OF THE INVENTION

(a) Technical Field of the Invention

The present invention relates to a method of manufacturing heat dissipation device, and in particular, a method which is safe to be implemented in the manufacturing process.

(b) Description of the Prior Art

In the process of computer operation, temperature from ICs and chips are produced. If the temperature of the working environment of the computer exceeds a certain limitation, the computer may not function well and therefore a heat dissipation device needs to be installed to the computer to disperse the heat accumulated. The conventional heat dissipation devices are made from aluminum material and the efficiency of heat dissipation is limited. The thermal coefficient of aluminum is 0.051 Kcal/ns.deg.C., which is smaller than that of copper being 0.092 Kcal/ms.deg.C., and thus, the thermal coefficient of copper is greater than that of aluminum

Commonly, there are two types of heat dissipation devices with respect of heat dissipation fins:

(1) combination heat dissipation fins: As zinc solder 11 is used for soldering the heat dissipation fins 12 to the heat dissipation seat 10, the colors of the zinc and copper are not matched and the overall color of the structure does not provide an aesthetic appearance. Further, the soldering process will produce oxidized copper (rust) which will affect heat dissipation efficiency.

(2) One unit heat dissipation fins: A copper block is cut to form into a plurality of fins. However, this process is a waste of time and material. Besides, the fins have increased the overall weight of the device.

### SUMMARY OF THE INVENTION

Accordingly, it is an object of the present invention to provide a method of manufacturing heat dissipation device, comprising the steps of a pressing copper plates or boards of appropriate thickness to form heat dissipation seat and heat dissipation fin of appropriate shape; surface-furnishing of heat dissipation seat; surface cleaning and treatment of the heat dissipation seat and heat dissipation fins under a protective gas; soldering with silver in an oven by coating the heat dissipation seat and heat dissipation fins with a silver solder; performing an anti-oxidant process for copper on the heat dissipation seat and heat dissipation sinks from the oven; and riveting or mounting a top cover for fixing a fan onto the heat dissipation seat.

The foregoing object and summary provide only a brief introduction to the present invention. To fully appreciate these and other objects of the present invention as well as the invention itself, all of which will become apparent to those skilled in the art, the following detailed description of the invention and the claims should be read in conjunction with the accompanying drawings. Throughout the specification and drawings identical reference numerals refer to identical or similar parts.

Many other advantages and features of the present invention will become manifest to those versed in the art upon making reference to the detailed description and the accompanying sheets of drawings in which a preferred structural embodiment incorporating the principles of the present invention is shown by way of illustrative example.

### BRIEF DESCRIPTION OF THE DRAWINGS

FIG. 1 is an enlarged sectional view of soldering section of a conventional heat dissipation device.

FIG. 2 is a flow chart showing the manufacturing process of the present invention.

FIG. 3 is a perspective exploded view of a heat dissipation device in accordance with the present method.

FIG. 4 is a perspective exploded view of a heat dissipation device of another preferred embodiment.

FIG. 5 is a sectional view of the heat dissipation device of the present invention.

FIG. 6 is an enlarged view of the silver-soldering section of the heat dissipation device in accordance with the present invention.

FIG. 7 is a sectional view of a heat dissipation device in accordance with another preferred embodiment of the present invention.

FIG. 8 is a flowchart of manufacturing a heat dissipation device of another preferred embodiment in accordance with the present invention.

FIG. 9 is an analytical view in accordance with the present invention.

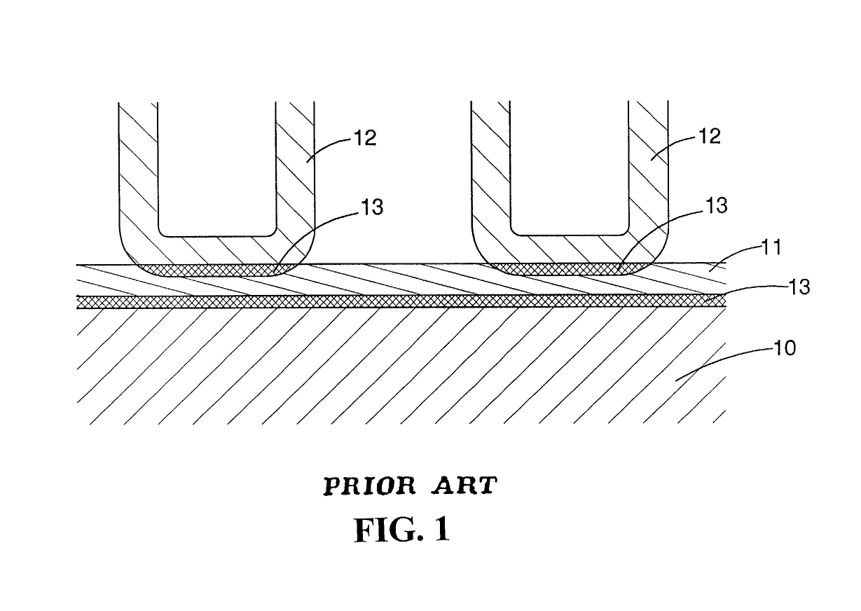

### DETAILED DESCRIPTION OF THE PREFERRED EMBODIMENT

The following descriptions are of exemplary embodiments only, and are not intended to limit the scope, applicability or configuration of the invention in any way. Rather, the following description provides a convenient illustration for implementing exemplary embodiments of the invention. Various changes to the described embodiments may be made in the function and arrangement of the elements described without departing from the scope of the invention as set forth in the appended claims.

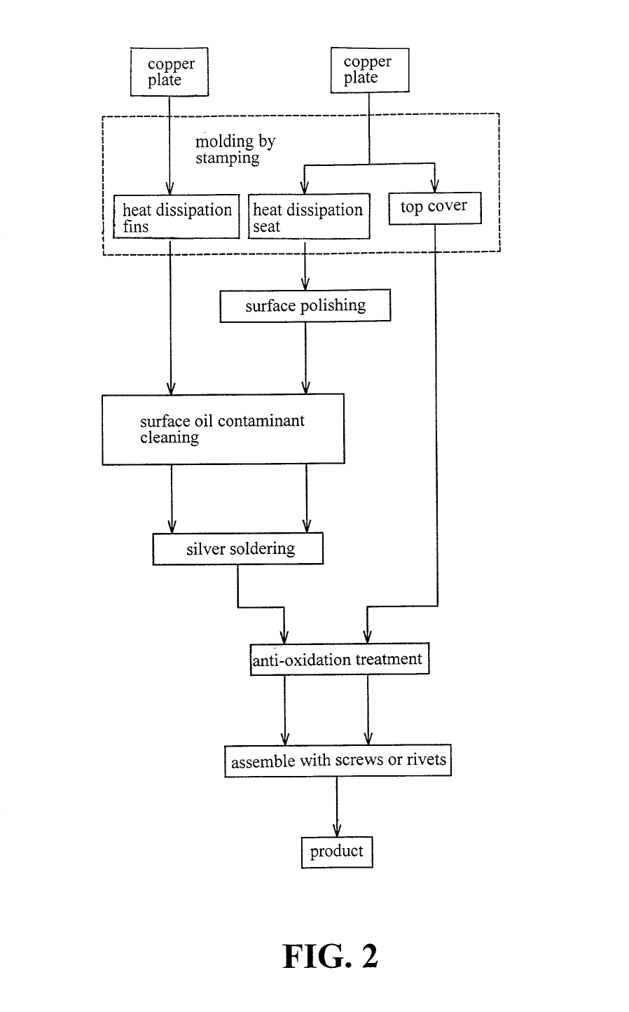

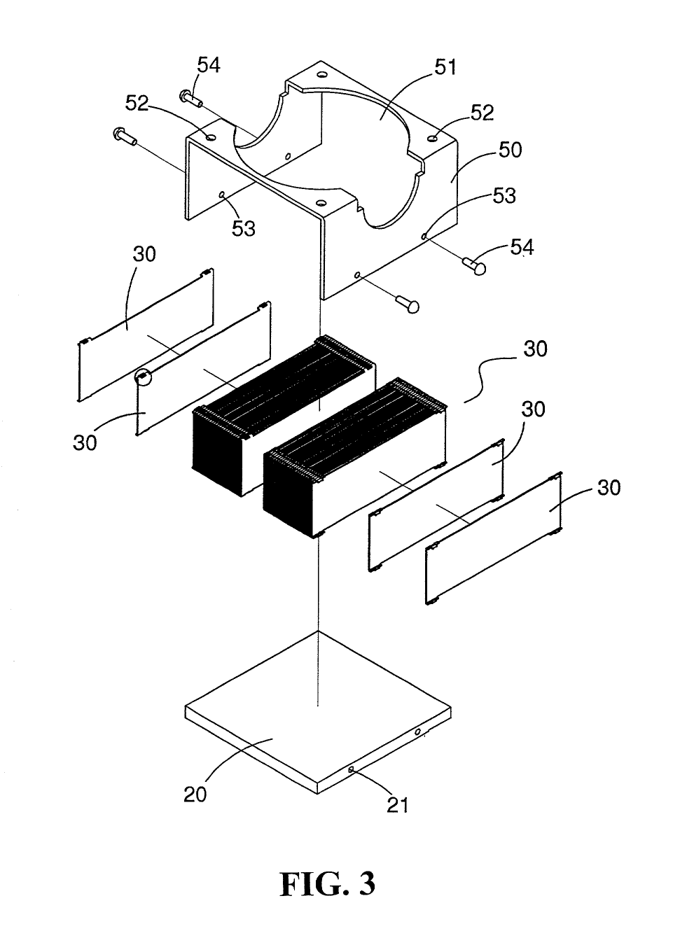

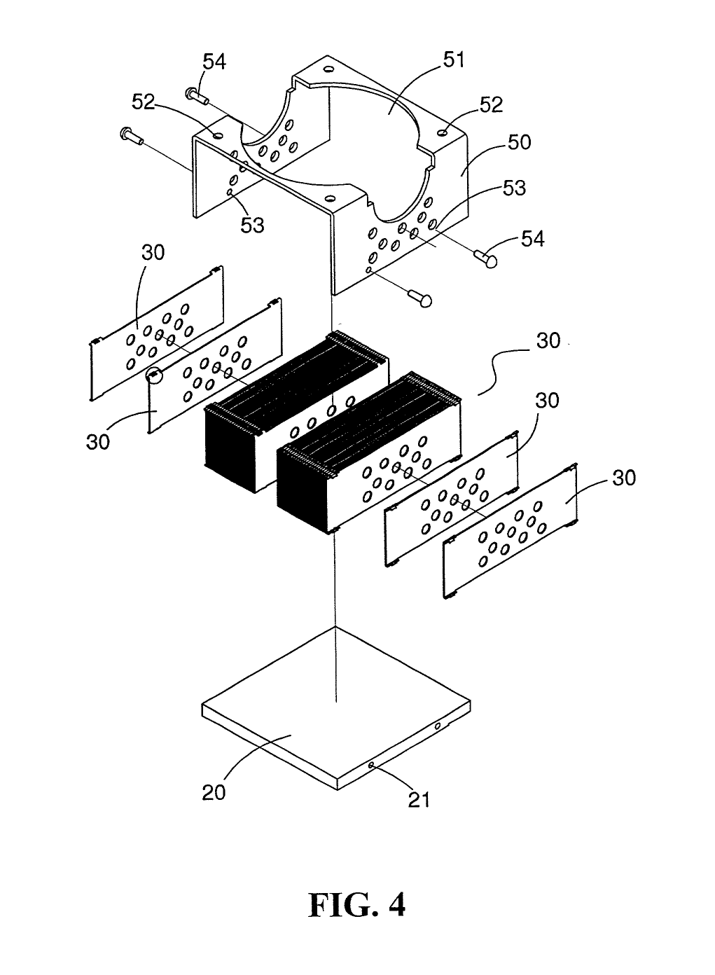

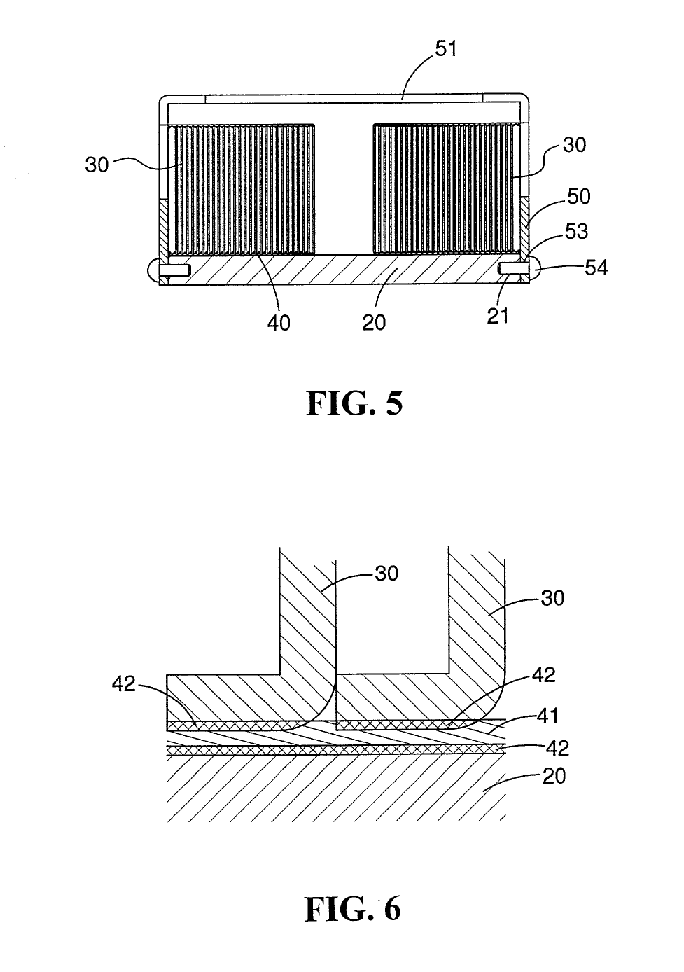

Referring to FIGS. 2 to 4, there is shown a method of manufacturing heat dissipation device. The sequences of the present method are:

(I) STAMPING PROCESS:

Copper plate of appropriate thickness is stamped and bent to form a specific size and shape heat dissipation seat 20 and a top cover 50, and the two lateral sides of the seat 20 are provided with a plurality of fixing holes 21, and the top of the top cover 50 is provided with a hole 51 for the air stream produced by a fan, and a locking hole 52 for the mounting of the fan. The lower edges of the top cover 50 are provided with a plurality of through holes 53 and copper plates with a thinner thickness are stamped to form a plurality of heat dissipation fins 30 which can be hooked to each other.

(II) SURFACE POLISHING:

The prepared heat dissipation seat 20 and the top cover 50 are undergone a surface polishing treatment.

(III) CLEANING OF SURFACE OIL CONTAMINANT TREATMENT:

The heat dissipation seat 20 and the heat dissipation fins 30 are placed within a protective gas containing 90% of Nitrogen, 7% of hydrogen and 3% of other gases, and cleaning of surface oil-contaminant process is carried out at a temperature above 700° C. to achieve 100% cleaning without using a solder.

(IV) SILVER SOLDERING TREATMENT:

Silver solder is coated between the heat dissipation seat 20 and the heat dissipation fins 30 and then the seat 20 is placed in oven at about 850° C. to 900° C. so that the heat dissipation fins 30 are soldered onto the heat dissipation seat 20. The contents of the silver solder 40 are silver 60%, copper 35%, Ni—Cr 5%, wherein the silver component is used to increase the efficiency of conduction. Copper is used to provide siphoning effect during melting process. Nickel-Chromium is used to increase the hardness.

(V) ANTI-OXIDATION TREATMENT:

After the heat dissipation seat 20 and the heat dissipation fins 30 are taken out from the oven, together with the top cover, they are proceeded to anti-oxidation treatment.

(VI) ASSEMBLY:

Rivets are used and are inserted into the through hole 53 and the fixing hole 21 so that the top cover 50 is fixed to the heat dissipation seat 20.

Referring to FIG. 6, the fins 30 can be made from copper plates which are stamped to form a plurality of recesses or dents.

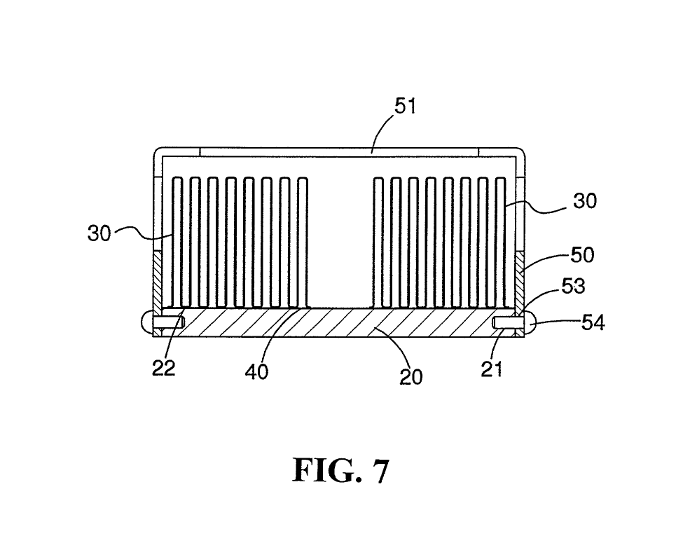

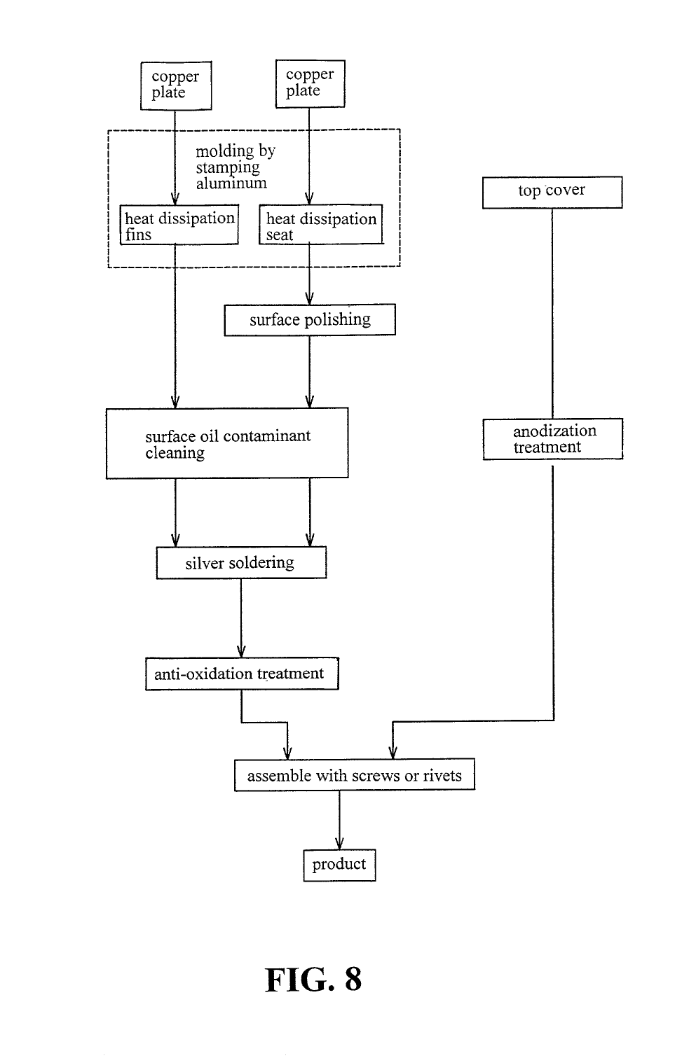

FIG. 7 shows a top cover 50 made from aluminum material where heat conduction is not a requirement for the heat dissipation device. However, the aluminum has proceeded to an anodization process.

The advantages of the present invention are as follows:

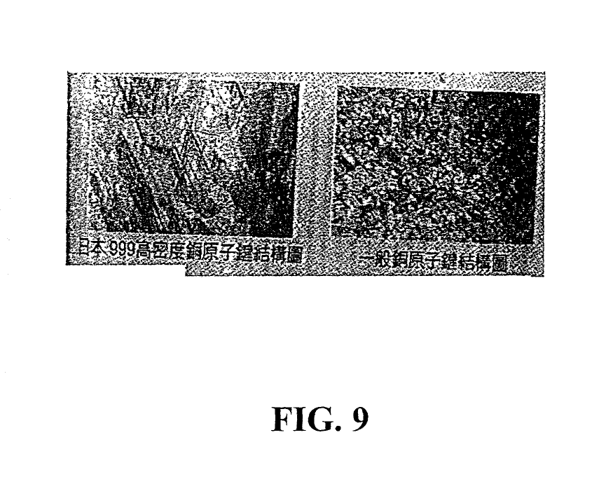

(1) Excellent heat dissipation: Due to the formation of copper-silver alloy between the heat dissipation fins 30 and the heat dissipation seat 20 with the silver solder 40, heat conduction is greatly improved. This can be seen in FIG. 9, wherein the heat dissipation device is employed in a mother board model A7133, with CPU Duron 700 MHz and operating under Chinese Version Windows 2000.

(2) Safe working environment: Due to the 100% clean surface, no solder is needed and therefore, toxic gas will not evolve.

(3) No contamination to the environment: Prior to silver soldering process, the heat dissipation seat and the heat dissipation fins 30 are undergone a protective gas treatment and this treatment does not contaminate the environment.

(4) No impact to the aesthetic appearance: The color of the silver solder is the same as that of the heat dissipation seat 20 and the heat dissipation fins 30, therefore, the overall color after the soldering process is the same and the aesthetic appearance of the structure is not affected.

It will be understood that each of the elements described above, or two or more together may also find a useful application in other types of methods differing from the type described above.

While certain novel features of this invention have been shown and described and are pointed out in the annexed claim, it is not intended to be limited to the details above, since it will be understood that various omissions, modifications, substitutions and changes in the forms and details of the device illustrated and in its operation can be made by those skilled in the art without departing in any way from the spirit of the present invention.

I claim:

1. A method of manufacturing heat dissipation device, comprising the steps of:
(a) stamping copper plates or boards of appropriate thickness to form heat dissipation seat and heat dissipation fins of appropriate shape;
(b) surface-furnishing of heat dissipation seat;
(c) surface oil-contaminant cleaning and treatment of the heat dissipation seat and heat dissipation fins under a protective gas;
(d) soldering with silver in an oven by coating the space between the heat dissipation seat and heat dissipation fins with a silver solder;
(e) performing an anti-oxidant process for copper on the heat dissipation seat and heat dissipation fins from the oven; and
(f) riveting or mounting a top cover for fixing a fan onto the heat dissipation seat.

2. The method of claim 1, wherein a plurality of fixing holes are mounted at the two lateral sides of the heat dissipation seat for the riveting or mounting of the top cover, and the heat dissipation fins are copper plate bodies with hooks with each other.

3. The method of claim 2, wherein the plate bodies are provided with a plurality of through holes.

4. The method of claim 1, wherein the top cover is arch-shaped made from copper plate having air hole for the air stream produced by the fan, and a locking hole for fixing the fan, and a plurality of holes are provided at the lower section of the two sides of the plate for mounting or riveting.

5. The method of claim 1, wherein the protective gas contains nitrogen 90%, hydrogen 7%, and other gases 3%.

6. The method of claim 1, wherein the temperature of silver soldering is about 850° C. to 900° C.

7. The method of claim 1, wherein the heat dissipation fins are copper plates continuously stamped to form a plurality of dents thereon.

8. The method of claim 1, wherein the top cover is made from aluminum and is then undergone an anodization process.

9. The method of claim 1, wherein the contents of silver solder are silver 60%, copper 35%, and Ni—Cr 5%.
